(19) United States
(12) Patent Application Publication
(10) Pub. No.: US 2007/0058760 A1
(43) Pub. Date: Mar. 15, 2007

(54) Apparatus and method for transmitting data in a communication system

(75) Inventor: Seung-Il Jeong, Yongin-si (KR)

Correspondence Address: DILWORTH & BARRESE, LLP, 333 EARLE OVINGTON BLVD., UNIONDALE, NY, 11553, US

(73) Assignee: Samsung Electronics Co., Ltd.

(21) Appl. No.: 11/503,723

(22) Filed: Aug. 14, 2006

(30) Foreign Application Priority Data
Aug. 12, 2005 (KR) 74182-2005

(51) Int. Cl. H03D 1/04

(52) U.S. Cl. 375/346

(57) ABSTRACT

Disclosed are a data transmission apparatus and a data transmission method for preventing signal interferences from being caused by cross-talk between respective paths in a communication system configured in a mesh interface structure. There is provided a method for transmitting data through inter-module interfaces in a communication system in which a mesh interface structure is formed between at least two modules constituting the communication system, the method including configuring different code information according to packaging positions of the respective modules, and containing the configured different information in transmission data of the respective modules and transmitting the transmission data through the inter-module interfaces forming the mesh interface structure.

This application claims the benefit under 35 U.S.C. § 119(a) of an application applications filed in the Korean Industrial Property Office on Aug. 12, 2005, and assigned Ser. No. 2005-74182, the contents of which are incorporated herein by reference.

### BACKGROUND OF THE INVENTION

1. Field of the Invention

The present invention relates generally to a communication system configured in a mesh interface structure, and in particular, to a data transmission apparatus and a data transmission method that can prevent signal interferences being caused by cross talk between respective paths in a communication system configured in a mesh interface structure.

2. Description of the Related Art

In general, a mesh interface structure in a communication system refers to a structure in which interfaces between various modules constituting a wireless communication system form a mesh structure. Such a mesh interface structure has flexibility in interfacing between a channel card for performing modulation/demodulation into a prescribed signal when data is transmitted/received into a wireless environment and a transceiver card for performing up/down conversion of a base band signal into a Radio Frequency (RF) band signal or vice versa. For example, the channel card must be increased in order to expand the capacity of processing subscribers, and the transceiver card must be increased in order to increase the number of usable frequencies according to a frequency distribution. In such situations, the mesh interface structure enables interfaces between the increased channel and transceiver cards to be flexibly determined.

FIG. 1 schematically illustrates a mesh interface structure of a Radio Access Station (RAS) in a communication system. Referring to FIG. 1, in the mesh interface structure of the RAS serving as a Base Station (BS) in the communication system, a mesh structure is formed between Hpi Channel Element Packet Data Board Assembly (HEPA) modules (HEPA0, HEPA1, HEPA2, HEPA3, HEPA4) 111, 112, 113, 114, 115, respectively, as a channel card 110 for performing a modulation/demodulation function according to a system standard, and Hpi Intermediate Frequency Board Assembly (HIFA) modules (HIFA0, HIFA1, HIFA2, HIFA3, HIFA4) 121, 122, 123, 124, 125, respectively, as a transceiver card 120 for performing up/down conversion of a base signal into an RF signal.

A Multi Gigabit Transceiver (MGT) scheme is used as an interface technology for providing the mesh interface structure between the HEPA and HIFA modules in such a communication system, and the MGT scheme can be divided into a High-Speed Serializer/Deserializer (“SerDes”) interface scheme, a parallel synchronization interface scheme and a source synchronization interface scheme.

FIG. 2 schematically illustrates data transmission according to a SerDes interface scheme in a communication system configured in a mesh interface structure.

Referring to FIG. 2, the SerDes interface scheme is an interface scheme in which a transmitting-end 210 of a HEPA module converts data from a parallel format to a serial format and transmits the converted serial data to a receiving-end 220 of a HIFA module, which, in turn, reconverts the received data from the serial format to the parallel format. That is, the transmitting-end 210 of the HEPA module converts parallel data, which is input over sixteen (16) paths, into serial data through a serializer 212, and then transmits the converted serial data to the receiving-end 220 of the HIFA module over one path. Here, the speed at which the serial data is transmitted over one path is approximately 16 times faster than the speed at which the parallel data is input over 16 paths. Further, the receiving-end 220 of the HIFA module restores the received serial data to the parallel data through a deserializer 222, and then outputs the recovered parallel data over 16 paths. Such a SerDes interface scheme simplifies a connection between the HEPA and HIFA modules interfaced to each other by connecting both the modules via one path, and brings favorable synchronization between both modules by employing a source synchronization interface scheme.

FIGS. 3A and 3B schematically illustrate data transmission according to a parallel synchronization interface scheme in a communication configured in a mesh interface structure. Referring to FIG. 3A, the parallel synchronization interface scheme is an interface scheme in which a transmitting-end 310 of a HEPA module shares and uses a common clock line with a receiving-end 320 of a HIFA module for establishing synchronization between the HEPA and HIFA modules. Thus, a common clock is applied to the transmitting-end 310 of the HEPA module and the receiving-end 320 of the HIFA module and, according to the common clock, the transmitting-end 310 of the HEPA module transmits data d0, d1, d2 to the receiving-end 320 of the HIFA module over 16 paths. Here, in order to achieve exact synchronization between both modules, the length of the clock lines supplied to both modules must be equal, and a skew between clocks arriving to both of the modules must be minimized. Further, in the parallel synchronization interface scheme, sufficient margins of a setup time and a hold time must be provided to the common clock so that, according to the common clock, the receiving-end 320 of the HIFA module can receive non-erroneous data d0, d1, d2, as illustrated in FIG. 3B.

FIG. 4 schematically illustrates data transmission according to a source synchronization interface scheme in a communication system configured in a mesh interface structure.

Referring to FIG. 4, the source synchronization interface scheme is a serial synchronization interface scheme contrasted with the parallel synchronization interface scheme, and it is frequently used for high-speed data interfacing. That is, in the source synchronization interface scheme, a separate common clock is not used for synchronization between a transmitting-end 410 of a HEPA module and a receiving-end 420 of a HIFA module, but only clocks extracted from traffic data of a data line are used for the synchronization between both modules. Thus, the transmitting-end 410 of the HEPA module combines parallel data with a fundamental clock through a 16 times (×16) Phase Locked Loop (PLL) module 412, and then transmits serial data to the receiving-end 420 of the HIFA module over one path. Here, the ×16 PLL module is a phase locked loop providing an output clock with frequency corresponding to 16 times of the frequency of an input clock, and the output clock is output with the input clock phase-locked.

Here, the speed at which the serial data is transmitted over one path is approximately 16 times faster than the speed at which the parallel data is input according to the fundamental clock. Further, the receiving-end 420 of the HIFA module recovers a clock through a Clock Data Recovery (CDR) block 422 in one transmission path, that is, the data line, and then extracts data through the recovered clock. In such a source synchronization interface scheme, data can be extracted at the most ideal timing even though margins of a setup time and a hold time are not sufficient in the clock of the receiving-end 420 of the HIFA module.

As such, a RAS in a communication system can include a plurality of HEPA and HIFA modules in order to ensure appropriate channel processing capacity through the mesh interface structure. For example, the RAS can form a flexible mesh interface structure by including one HEPA module and one HIFA module in the case of a communication system having a 1FA/1sector architecture, and by including three (3) HEPA modules and one HIFA module in the case of a communication system having a 1FA/3sector architecture. Here, it is common knowledge that one HEPA module can process one sector, and one HIFA module can process three sectors.

In such a mesh interface structure of a RAS in a communication system, cross-talk between respective paths can occur. Additionally, errors in data transmission over the paths can occur because signal interferences between adjacent paths are caused by the cross-talk. For example, since each of HIFA modules as a transceiver card processes 1FA/3sectors and each of HEPA modules as a channel card processes a 1FA/1sector, the RAS includes one HIFA module and two (2) HEPA modules in the case of a communication system having a 1FA/2sector architecture. Thus, one HIFA modules places its line in a floating state such that it can further process one sector. Then, a signal can be received from the HEPA module to the line in the floating state, and the so-received signal gives rise to errors in data transmission. Here, the cross-talk refers to a phenomenon in which electrical coupling, such as electrostatic coupling or electromagnetic coupling, between signals on different paths causes the signals to be affected by each other.

Reference will now be made to data transmission according to a mesh interface MGT scheme, which a RAS performs in a communication system, with reference to FIG. 5. FIG. 5 schematically illustrates a concept in which a RAS MGT scheme.

Referring to FIG. 5, a transmitting-end 510 of a HEPA module converts input parallel data 516 into serial data 530 through a serializer 512, and then transmits the converted serial data 530 to a receiving-end 520 of a HIFA module. Here, the parallel data 516 includes traffic data 513, 515 having a parallel format, and a comma code 514 also having a parallel format and interposed between the traffic data 513, 515. The comma code 514 as a parallelization code is dummy data transmitted together with actual traffic data 513, 515 over a data line, and is used when the receiving-end 520 of the HIFA module converts the serial data 530 into parallel data 526, as will be described herein below. The traffic data 513, 515 and the comma code 514, all of which have a parallel format, are converted into the serial data 530 by means of the serializer 512, and the converted serial data is transmitted to the receiving-end 520 of the HIFA module. Here, the serial data 530 has a structure in which a comma code 532 having a serial format is interposed between traffic data 531, 533 configured in a serial format.

Upon receiving the serial data 530 from the transmitting-end 510 of the HEPA module, the receiving-end 520 of the HIFA module converts the traffic data 531, 533 into the parallel data 526 through a deserializer 522. Such conversion is performed based on the comma code 532 of the serial data 530. That is, the deserializer 522 converts the serial data 530 into traffic data 523, 525 having a parallel format and a conmma code 524 having a parallel format and interposed between the traffic data 523, 525. Thus, the receiving-end 520 of the HIFA module restores the received serial data 530 to the parallel data 516 input into the transmitting-end 510 of the HEPA module.

However, according to the MGT scheme in the RAS configured in the mesh interface structure, the comma code 514 interposed between the traffic data 513, 515 is the same in all paths between the transmitting-end 510 of the HEPA 513, 515 is the same in all paths between the transmitting-end 510 of the HEPA module and the receiving-end 520 of the HIFA module. That is, when there are a plurality of HEPA and HIFA modules, the respective modules interpose the same comma code between all of the respective traffic data. In other words, parallel data 516 in which the same comma code 514 is interposed between traffic data 513, 515 are converted into serial data 530, and the converted serial data are transmitted over the respective paths. Here, since the same comma code is inserted into all the data transmitted over the respective paths, cross-talk between adjacent paths can occur.

If the cross-talk between adjacent paths occurs in this manner, in the receiving-end 520 of the HIFA module having received the serial data 530, the comma code 532 can be received to a line placed in a floating state. Then, the receiving-end 520 of the HIFA module can mistakenly receive the comma code 532 for the traffic data 531, 533 although there is actually no traffic data 531, 533 in the line placed in the floating state, and thus the deserializer 522 of the receiving-end 520 can operate. There is a problem in that the comma code 532 received to the line placed in the floating state is useless data, but still the receiving-end 520 of the HIFA module converts this useless data into parallel data and transmits the converted parallel data into a wireless environment. Particularly, a system employing the MGT scheme determines whether a corresponding path is in a normal/abnormal state based on the reception of the comma code 532. Thus, as the comma code 532 is received to the line placed in the floating state, the system determines an abnormal state as a normal state. As a result of this, the system finally transmits the comma code 532 received due to the cross-talk, that is, the useless data, into the wireless environment.

### SUMMARY OF THE INVENTION

Accordingly, the present invention has been made to solve at least the above-mentioned problems occurring in the conventional art, and an object of the present invention is to provide an apparatus and a method for transmitting data in a communication system.

A further object of the present invention is to provide a data transmission apparatus and a data transmission method that can prevent signal interferences being caused by cross-talk between respective paths in a communication system configured in a mesh interface structure.

In order to accomplish these objects, in accordance with the present invention, there is provided a method for transmitting data through inter-module interfaces in a communication system in which a mesh interface structure is formed between at least two odules constituting the communication system, the method including configuring different code information according to packaging positions of the respective modules; and containing the configured different information in transmission data of the respective modules, and transmitting the transmission data through the inter-module interfaces forming the mesh interface structure.

In accordance with another aspect of the present invention, there is provided an apparatus for transmitting data through inter-module interfaces in a communication system in which a mesh interface structure is formed between at least two modules constituting the communication system, the apparatus including a data configuration unit for configuring different code information according to packaging positions of the respective modules; and a transmitter unit for containing the configured different information in transmission data of the respective modules, and transmitting the transmission data through the inter-module interfaces forming the mesh interface structure.

### BRIEF DESCRIPTION OF THE DRAWINGS

The above and other objects, features and advantages of the present invention will be more apparent from the following detailed description taken in conjunction with the accompanying drawings, in which:

FIG. 1 is a block diagram schematically illustrating a mesh interface structure of a Radio Access Station (RAS) in a communication system;

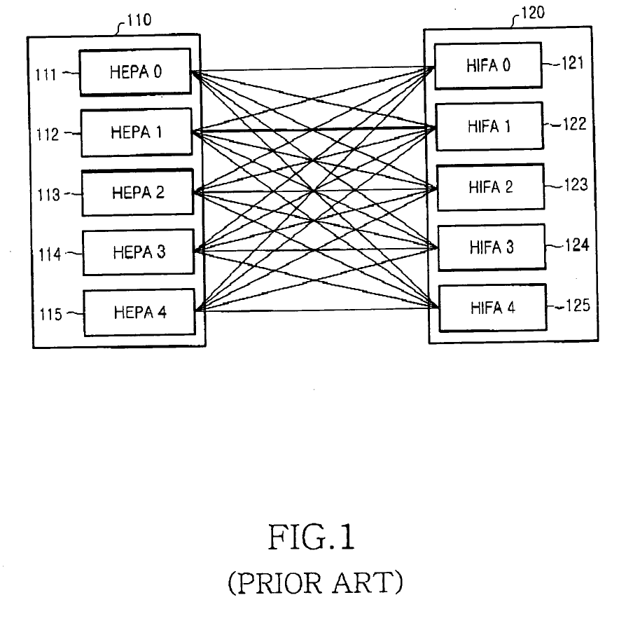

FIG. 2 is a block diagram schematically illustrating data transmission according to a SerDes interface scheme in the mesh interface structure of FIG. 1;

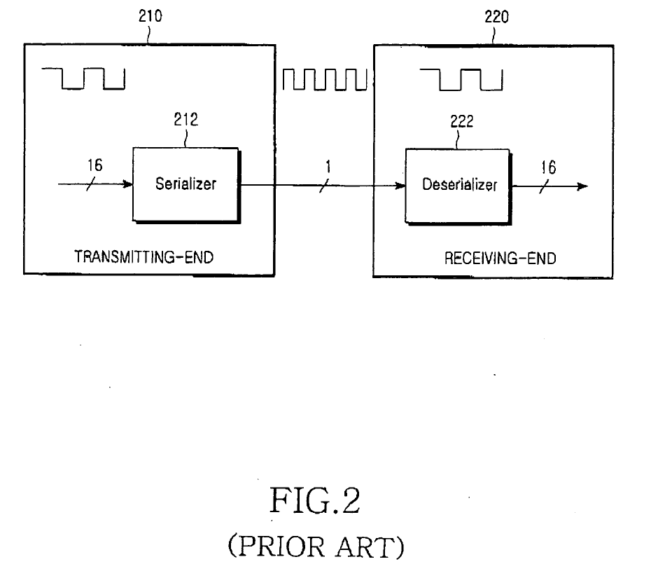

FIGS. 3a and 3b are views schematically illustrating data transmission according to a parallel synchronization interface scheme in the mesh interface structure of FIG. 1;

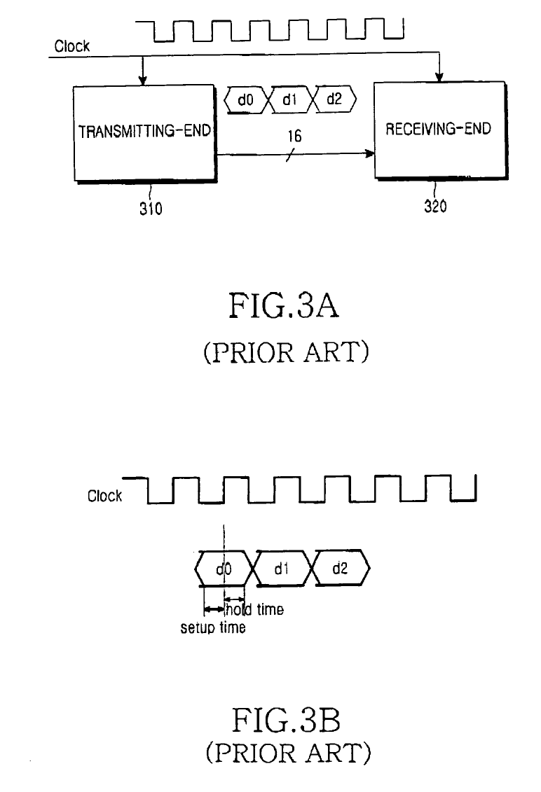

FIG. 4 is a block diagram schematically illustrating data transmission according to a source synchronization interface scheme in the mesh interface structure of FIG. 1;

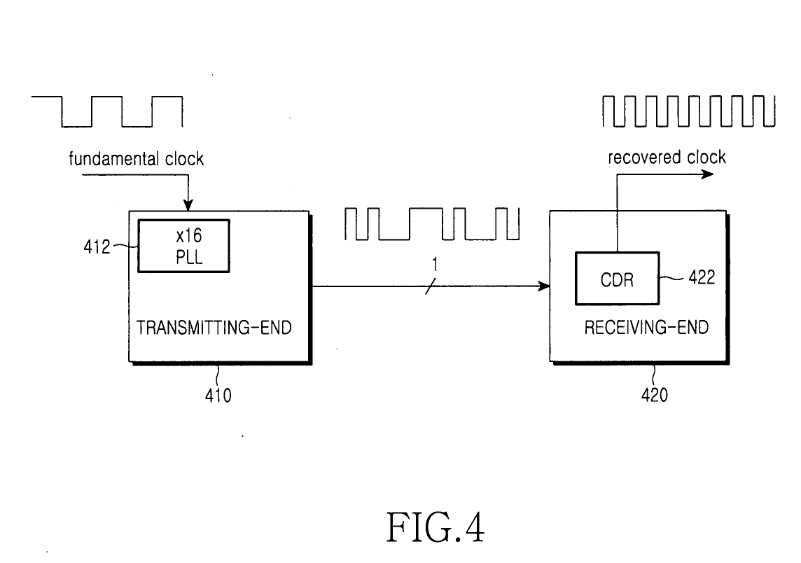

FIG. 5 is a block diagram schematically illustrating data transmission according to a MGT scheme in the mesh interface structure of FIG. 1;

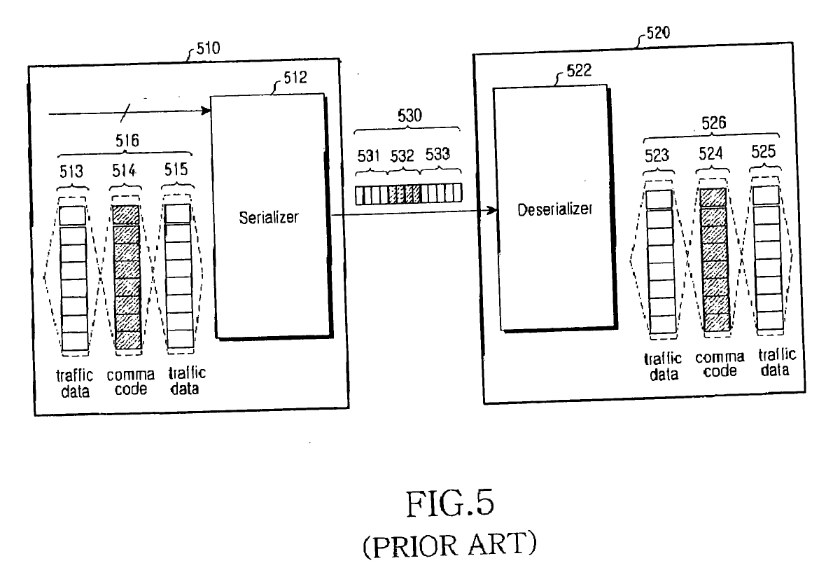

FIG. 6 is a block diagram schematically illustrating an apparatus for preventing signal interferences in a communication system configured in a mesh interface structure in accordance with the present invention;

FIG. 7 is a flowchart schematically illustrating a procedure of preventing signal interferences in a communication system configured in a mesh interface structure in accordance with the present invention;

FIG. 8 is a block diagram schematically illustrating a mesh interface structure of a RAS in a communication system in accordance with the present invention; and

FIG. 9 is a block diagram schematically illustrating data transmission in the mesh interface structure of FIG. 8.

### DETAILED DESCRIPTION OF THE PREFERRED EMBODIMENT

Preferred embodiments of the present invention will be described with reference to the accompanying drawings. It should be noted that similar components are designated by similar reference numerals although they are illustrated in different drawings. In the following description, a detailed description of known functions and configurations incorporated herein will be omitted when it may obscure the subject matter of the present invention.

The present invention provides a data transmission apparatus and a data transmission method. , An apparatus and a method for transmitting data in a communication system configured in a mesh interface structure are provided, which discern respective paths between modules from each other by setting different data paths for the modules according to the packaging positions of the modules packaged in the communication system, thereby preventing signal interferences from being caused by cross-talk between adjacent paths.

Hereinafter, the present invention will be described by an example in which a mesh interface structure is formed between a channel card (e.g., HEPA module) of a RAS, which serves as a Base Station (BS) in a communication system, and a transceiver card (e.g., HIFA module) of the RAS, and a MGT scheme is used as an interface technology providing the mesh interface structure. However, in addition to the communication system employing the MGT scheme, the present invention can be applied to other communication systems having the mesh interface structure.

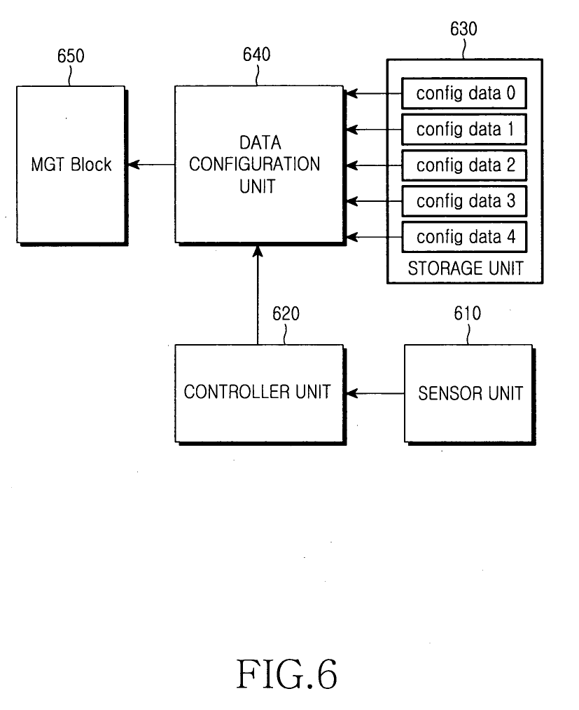

FIG. 6 illustrates an apparatus for preventing cross-talk between HEPA and HIFA modules of an RAS, which form a mesh interface structure, in a communication system according to the present invention. Referring to FIG. 6, the apparatus for preventing cross-talk in a RAS having a mesh interface structure includes a sensor unit 610 for detecting the packaging positions of respective modules, that is, HEPA and HIFA modules, a controller unit 620 for determining corresponding data according to the packaging positions of the respective modules, which is detected through the sensor unit 610, a storage unit 630 for storing given parameters, and a data configuration unit 640 for configuring MGT data, that is, a comma code and transmitting the configured MGT data to a MGT block 650. Here, the MGT block 650 includes the HEPA and HIFA modules in the RAS having the mesh interface structure.

The sensor unit 610 detects slot IDs, which have been previously provided to the backplane of the RAS according to the packaging positions of the respective modules, in order to locate the modules, that is, the HEPA and HIFA modules. Simply, the backplane of the RAS is previously provided with different slot IDs according to respective slots in which the modules are packaged. If a module is packaged in each slot, the sensor unit 610 detects the slot ID of the slot with the module packaged therein. Using the slot ID detected by the sensor unit 610, the controller unit 620 determines data corresponding to the detected slot ID from among data already allocated according to the slots. In this way, the controller unit 620 determines data corresponding to the packaging position of the module packaged in the RAS, and transmits the determined data to the data configuration unit 640.

The storage unit 630 stores parameters for a comma code, config data0, config data1, config data2, config data3, config data4, in order to use a comma code as a parallelization code when the module packaged in the RAS converts serial data into parallel data. Further, the comma code parameters config data0, config data1, config data2, config data3, config data4 stored in the storage unit 630 are transmitted to the data configuration unit 640 such that the data configuration unit 640 can configure the comma code and interpose the configured comma code between traffic data.

The data configuration unit 640 configures MGT data through the comma code parameters config data0, config data1, config data2, config data3, config data4 transmitted from the storage unit 630 and the determined data transmitted from the controller unit 620, and transmits the configured MGT data to the MGT block 650. The data configuration unit 640 receives data corresponding to the packaging positions of the respective modules from the controller unit 620 when the respective modules are packaged in the RAS, and configures MGT data corresponding to the received data by using the comma code parameters config data0, config data1, config data2, config data3, config data4 received from the storage unit 630. That is, the data configuration unit 640 configures different comma codes according to the packaging positions of the respective modules and then transmits the MGT data, thereby enabling the MGT block 650 to set the MGT data. Simply, the MGT block 650 including the HEPA and HIFA modules sets different comma codes according to the packaging positions of the HEPA and HIFA modules by means of the MGT data received from the data configuration unit 640.

Utilizing the MGT data set in this manner, the MGT block 650 interposes different comma codes between traffic data contained in parallel data according to the packaging positions of the HEPA and HIFA modules when a transmitting-end of the HEPA module converts the parallel data into serial data and transmits the converted serial data to a receiving-end of the HIFA module. Here, as described above, the parallel data contains traffic data having a parallel format and a comma code interposed between the traffic data. Such parallel data is converted into the serial data at the transmitting-end of the HEPA module, and is transmitted to the receiving-end of the HIFA module.

Further, after receiving the serial data from the transmitting-end of the HEPA module, the receiving-end of the HIFA module converts the received serial data into parallel data based on the comma code, and transmits the converted parallel data into a wireless environment. Here, since the comma code is different according to the packaging positions of the respective modules, that is, the HEPA and HIFA modules, a different comma code is inserted into each parallel data. In this manner, since the transmitting-end of the HEPA module converts parallel data, into which a different comma code is inserted according to the packaging positions of modules, into serial data and transmits the converted serial data to the receiving-end of the HIFA module, cross-talk between the transmitting-end of the HEPA module and the receiving-end of the HIFA module does not occur.

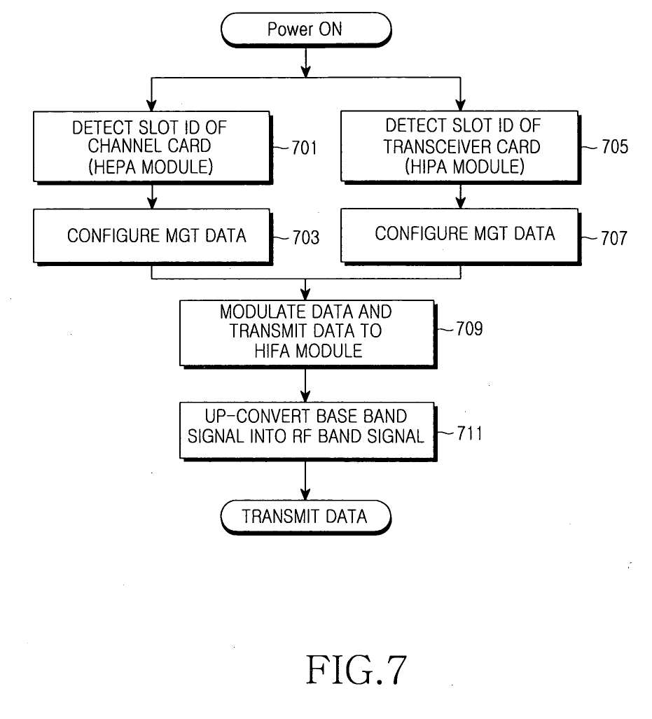

FIG. 7 is a flow chart illustrating an operational procedure of the above-mentioned apparatus for preventing cross-talk between HEPA and HIFA modules of a RAS, which forms a mesh interface structure, in a communication system.

Referring to FIG. 7, if the RAS is initially powered on, the sensor unit 610 of the apparatus detects the slot ID of the HEPA module in step 701 in order to locate the HEPA module as a channel card packaged in the RAS. Then, the controller unit 620 determines data corresponding to the slot ID detected by the sensor unit 610, from among data previously allocated according to the slots, and transmits the determined data to the data configuration unit 640. Simultaneously, the storage unit 630 transmits comma code parameters config data0, config data1, config data2, config data3, config data4 to the data configuration unit 640. Thereafter, in step 703, the data configuration unit 640 configures MGT data, that is, a comma code, through the comma code parameters config data0, config data1, config data2, config data3, config data4 and the determined data. In this manner, the data configuration unit 640 configures different MGT data, that is, different comma codes, according to the packaging positions of the HEPA modules, and sets the configured comma code for the HEPA modules.

If the RAS is initially powered on, the sensor unit 610 also detects the slot ID of the HIPA module in step 705 in order to locate the HIPA module as a transceiver card packaged in the RAS. Then, the controller unit 620 determines data corresponding to the slot ID detected by the sensor unit 610, from among data already allocated according to the slots, and transmits the determined data to the data configuration unit 640. At the same time, the storage unit 630 transmits comma code parameters config data0, config data1, config data2, config data3, config data4 to the data configuration unit 640. Thereafter, in step 707, the data configuration unit 640 configures MGT data, that is, a comma code, through the comma code parameters config data0, config data1, config data2, config data3, config data4 and the determined data. In this manner, the data configuration unit 640 configures different MGT data, that is, different comma codes, according to the packaging positions of the HIPA modules, and sets the configured comma code for the HIPA modules.

In this manner, if the RAS is initially powered on, different comma codes are set for the HEPA and HIFA modules, respectively according to the packaging positions of the respective modules, and then the HEPA module, a channel card of the RAS, converts parallel data, in which the comma code set corresponding to the packaging position of the HEPA module is interposed between traffic data, into serial data. That is, the HEPA module converts parallel data, which is discerned by the comma code set according to its packaging position, into serial data. The HEPA module also modulates the serial data into an Orthogonal Frequency Division Multiplexing (OFDM) signal prescribed in the communication system to generate a base band signal, and transmits the base band signal to the HIFA module. Here, when the communication system, in which the HEFA module is packaged, is a Code Division Multiple Access (“CDMA”) system, the HEPA module modulates the serial data into a CDMA signal prescribed in the CDMA system to generate a base band signal, and transmits the base band signal to the HIFA module.

Thereafter, in step 711, the HIFA module, a transceiver card of the RAS, converts the received serial data into parallel data, and up-converts the base band signal into a RF band signal. The RAS then transmits the parallel data of the RF band signal into a wireless environment.

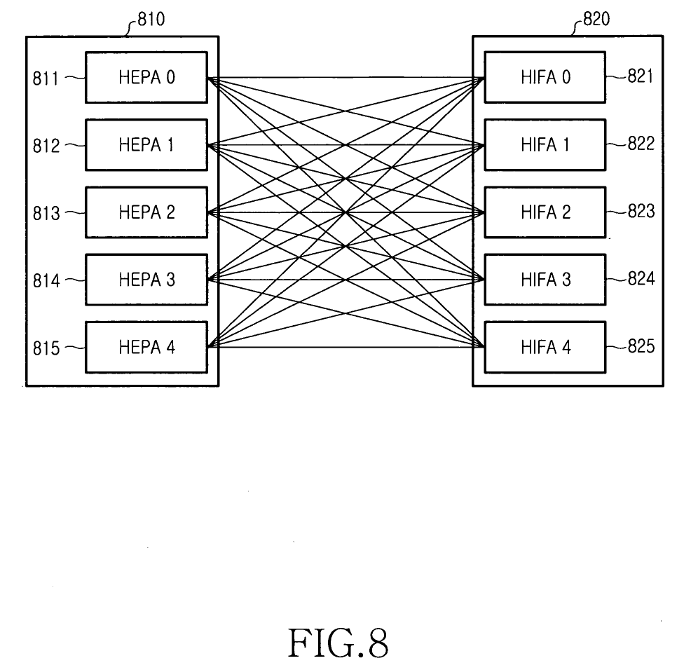

FIG. 8 illustrates a mesh interface structure between channel and transceiver cards of a RAS, that can prevent cross-talk between adjacent paths, in a communication system according to the present invention.

Referring to FIG. 8, in the mesh interface structure of the RAS, HEPA modules (HEPA0, HEPA1, HEPA2, HEPA3, HEPA4) 811, 812, 813, 814, 815, respectively, as a channel card 810, and HIFA modules (HIPA0, HIPA1, HIPA2, HIPA3, HIPA4) 821, 822, 823, 824, 825, respectively, as a transceiver card 820, and are packaged in the RAS while forming a mesh structure. Here, the HEPA modules 811, 812, 813, 814, 185 and the HIFA modules 821, 822, 823, 824, 825 have different slot IDs according to their packaging positions in the backplane of the RAS. Paths between the HEPA modules 811, 812, 813, 814, 185 and the HIFA modules 821, 822, 823, 824, 825 are discerned based on the slot IDs. If the RAS is powered on, the sensor unit 610 detects the respective slot IDs of the HEPA modules 811, 812, 813, 814, 185 and the HIFA modules 821, 822, 823, 824, 825 and delivers them to the controller unit 620. Using the detected slot IDs, the. controller unit 620 then determines data corresponding to the packaging positions of the HEPA modules 811, 812, 813, 814, 185 and the HIFA modules 821, 822, 823, 824, 825, from among data already allocated according to the slots.

The determined data are transmitted to the data configuration unit 640, and parameters for a comma code as a parallelization code, config data0, config data1, config data2, config data3, config data4, are also transmitted to the data configuration unit 640. Through these data and comma code parameters config data0, config data1, config data2, config data3, config data4, the data configuration unit 640 configures different comma codes according to the packaging positions of the HEPA modules 811, 812, 813, 814, 185 and the HIFA modules 821, 822, 823, 824, 825. Further, the data configuration unit 640 delivers the comma codes to the MGT block 650, so that comma codes corresponding to the packaging positions of the respective modules are set for the HEPA modules 811, 812, 813, 814, 185 and the HIFA modules 821, 822, 823, 824, 825, respectively.

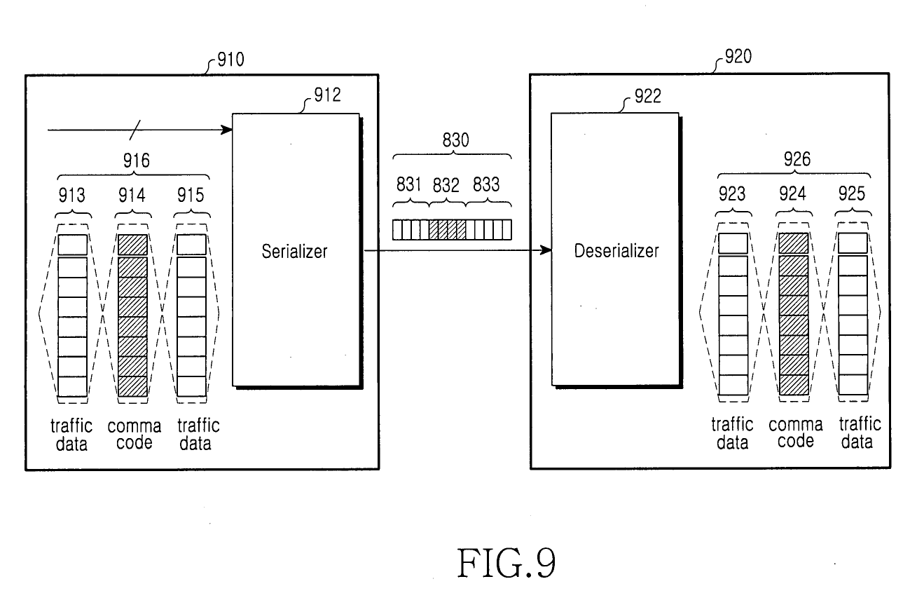

FIG. 9 illustrates data transmission between channel and transceiver cards forming a mesh interface structure according to the present invention. Here, FIG. 9 corresponds to a state where, when the RAS is initially powered on, different comma codes are set for the HEPA modules 811, 812, 813, 814, 185 and the HIFA modules 821, 822, 823, 824, 825, respectively according to their packaging positions, as described herein-above. Also, FIG. 9 illustrates a case where any one of the HEPA modules 811, 812, 813, 814, 185 transmits data to any one of the HIFA modules 821, 822, 823, 824, 825 by utilizing the MGT scheme.

Referring to FIG. 9, a transmitting-end 910 of the HEPA0 module 811 converts input parallel data 916 into serial data 930 through a serializer 912, and then transmits the converted serial data to a receiving-end 920 of the HIFA0 module 821. Here, the parallel data 916 includes traffic data 913, 915 having a parallel format, and a comma code 914 also having a parallel format and interposed between the traffic data 913, 915. As described above, the comma code 914 is a parallelization code set corresponding to the packaging positions of the HEPA0 module 811 and the HIFA0 module 821 when the RAS is powered on. That is, the comma code 914 is a comma code for a path between the HEPA0 module 811 and the HIFA0 module 821, and is different from other comma codes for paths between other HEPA and HIFA modules 812, 813, 814, 815, 822, 823, 824, 825. Also, the comma code 914 is useless data transmitted together with the traffic data 913, 195 over a data line, and is used as a point of reference when the serial data 930 is converted into parallel data. Such traffic data 913, 915 and such a comma code 514, all of which have a parallel format, are converted into the serial data 930 by means of the serializer 912, and the converted serial data 930 is transmitted to the receiving-end 920 of the HIFA0 module 821. Here, the serial data 930 has a structure in which a comma code 932 having a serial format is interposed between traffic data 931, 933 configured in a serial format.

After receiving the serial data 930 from the transmitting-end 910 of the HEPA0 module 811, the receiving-end 920 of the HIFA0 module 921 converts the traffic data 931, 933 into parallel data 926 through a deserializer 922. Such conversion is performed with reference to the comma code 932 of the serial data 930. That is, the deserializer 922 converts the serial data 930 into traffic data 923, 925 having a parallel format and a comma code 924 having a parallel format and interposed between the traffic data 923, 925. Thus, the receiving-end 920 of the HIFA0 module 821 recovers the received serial data 930 to the parallel data 916 input into the transmitting-end 910 of the HEPA0 module 811.

In this manner, according to the present invention, comma codes corresponding to the packaging positions of the HEPA modules 811, 812, 813, 814, 185 and the HIFA modules 821, 822, 823, 824, 825 are set for the HEPA modules 811, 812, 813, 814, 815 and the HIFA modules 821, 822, 823, 824, 825, respectively when the RAS is initially powered on in the communication system configured in the mesh interface structure. Accordingly, when the HEPA modules 811, 812, 813, 814, 815 transmit data to the HIFA modules 821, 822, 823, 824, 825, the HEPA modules 811, 812, 813, 814, 815 interpose different comma codes into traffic data, respectively according to the HIFA modules 821, 822, 823, 824, 825. That is, comma codes input into the respective transmitting-ends of the HEPA modules 811, 812, 813, 814, 815 are different form each other, and thus serial data transmitted over respective paths between the HEPA modules 811, 812, 813, 814, 815 and the HIFA modules 821, 822, 823, 824, 825 are also different from each other. As a result of this, the present invention can prevent cross-talk between adjacent paths from being caused by the same comma codes interposed between traffic data. Therefore, when there is a line placed in a floating state among the HIFA modules 821, 822, 823, 824, 825, a path corresponding to the line placed in the floating state does not exist. In addition, a comma code is not received to the floating line because the cross-talk is prevented as stated above. Further, in a system employing a MGT scheme, which judges if a corresponding path is in a normal/abnormal state based on whether a comma code is received, the present invention makes it possible to more exactly determine whether the corresponding path is in a normal/abnormal state. Particularly, since the present invention prevents the comma code from being received to the floating line in the communication system employing the MGT scheme, the system is prevented from mistaking an abnormal state for a normal state to transmit useless data into a wireless environment.

As described above, according to the present invention, different data are set according to the positions where modules are packaged in a communication system configured in a mesh interface structure, so that cross-talk in mesh interfaces between the modules can be prevented. Therefore, the present invention can prevent signal interferences from being caused by the cross-talk in the mesh interfaces, thereby improving system stability.

While the invention has been shown and described with reference to certain preferred embodiments thereof, it will be understood by those skilled in the art that various changes in form and details may be made therein without departing from the spirit and scope of the invention as defined by the appended claims and equivalents thereof.

What is claimed is:

1. A method for transmitting data through inter-module interfaces in a communication system in which a mesh interface structure is formed between at least two modules constituting the communication system, the method comprising the steps of:
configuring different code information according to packaging positions of the respective modules; and
containing the configured different information in transmission data of the respective modules, and transmitting the transmission data through the inter-module interfaces forming the mesh interface structure.

2. The method as claimed in claim 1, wherein the packaging positions of the respective modules are detected by means of slot identifier information about positions where the respective modules are packaged, from among slot identification information previously provided to the communication system.

3. The method as claimed in claim 2, wherein the code information is configured by data corresponding to the detected slot identifier information and parameters previously stored in the communication system.

4. The method as claimed in claim 3, wherein the data corresponding to the detected slot identifier information includes data corresponding to the detected slot identifier information, from among data allocated corresponding to the slot identification information previously provided to the communication system.

5. The method as claimed in claim 1, wherein the code information is configured when the communication system is initially powered on, and then is set for the respective modules.

6. An apparatus for transmitting data through inter-module interfaces in a communication system in which a mesh interface structure is formed between at least two modules constituting the communication system, the apparatus comprising:
a data configuration unit for configuring different code information according to packaging positions of the respective modules; and
a transmitter unit for containing the configured different information in transmission data of the respective modules, and transmitting the transmission data through the inter-module interfaces forming the mesh interface structure.

7. The apparatus as claimed in claim 6, wherein the further includes a sensor unit for detecting slot identifier information about positions where the respective modules are packaged, from among slot identification information previously provided to the communication system.

8. The apparatus as claimed in claim 7, wherein the data configuration unit configures the code information by data corresponding to the slot identifier information detected by the sensor unit and parameters previously stored in the communication system.

9. The apparatus as claimed in claim 8, wherein the data corresponding to the detected slot identifier information includes data corresponding to the detected slot identifier information, from among data allocated corresponding to the slot identification information previously provided to the communication system.

10. The apparatus as claimed in claim 6, wherein the data configuration unit configures the code information when the communication system is initially powered on, and then sets the code information for the respective modules.
